(19) United States
(12) Patent Application Publication
(10) Pub. No.: US 2025/0123567 A1
(43) Pub. Date: Apr. 17, 2025

(54) POLYSILOXANE COMPOSITION

(71) Applicant: Merck Patent GMBH, Darmstadt (DE)

(72) Inventors: Megumi Yano, Shizuoka (JP); Kensuke Aida, Fukuroi Shizuoka (JP)

(21) Appl. No.: 18/999,387

(22) Filed: Dec. 23, 2024

Related U.S. Application Data
(63) Continuation of application No. PCT/EP2023/067220, filed on Jun. 26, 2023.

(30) Foreign Application Priority Data
Jun. 28, 2022 (JP) 2022-103912

(51) Int. Cl. G03F 7/075; C08G 77/00; C08G 77/04; G03F 7/004; G03F 7/16

(52) U.S. Cl. CPC G03F 7/0757; C08G 77/04; G03F 7/0048; G03F 7/168; C08G 77/80

(57) ABSTRACT

A polysiloxane composition capable of being cured at a low temperature and having good storage stability is provided in a composition that includes (I) a polysiloxane having a certain structure as defined herein, (II) an ionic liquid, (III) an acid, and (IV) a solvent.

### CROSS-REFERENCE TO RELATED APPLICATIONS

This application is a Continuation under 35 USC § 111(a) of International Patent Application No. PCT/EP2023/067220, filed Jun. 26, 2023, which claims priority to Japanese Patent Application No. JP2022-103912, filed on Jun. 28, 2022. Both applications are hereby incorporated in their entirety.

### BACKGROUND OF THE INVENTION

### Technical Field

The present invention relates to a polysiloxane composition. Further, the present invention relates to a method for manufacturing a film using the same, a film using the same, and a method for manufacturing an electronic device comprising the film.

### Background Art

Polysiloxane is known to have resistance to elevated temperature. When a cured film is formed from a composition containing a polysiloxane, the coating film is heated at an elevated temperature to rapidly proceed with a condensation reaction of silanol groups in the polysiloxane and a reaction of a polymer having an unsaturated bond to cure the film. If unreacted reactive groups remain, they may react with the chemicals to be used in the device manufacturing process. Due to the influence on other materials in the substrate and from the device conditions, the development of a composition containing polysiloxane capable of being cured at a lower temperature has been desired.

For the purpose of curing an epoxy resin at a low temperature, the combination of an epoxy resin, an anionic polymerizable curing agent and an ionic liquid has been proposed in JP 2019-014781A, and in a comparative example where no anionic polymerizable curing agent is contained, any curing is not caused.

### SUMMARY OF THE INVENTION

### Problems to be Solved by the Invention

The present invention has been made in view of the above circumstances and provides a polysiloxane composition capable of being cured at a low temperature and having good storage stability. Further, its object is to provide, using the same, methods for manufacturing cured film and an electronic device.

### Means for Solving the Problems

A polysiloxane composition according to the present invention comprises:
(I) a polysiloxane including a repeating unit represented by the formula (Ia) and having silanol at the end or side chain, wherein when the polysiloxane is measured and analyzed by an FT-IR method, S2/S1 that is a ratio of an integrated intensity S1 of an absorption band assigned to Si—O in a range of 1100±100 cm⁻¹ to an integrated intensity S2 of an absorption band assigned to SiOH in a range of 900±100 cm⁻¹ is 0.010 to 0.10,

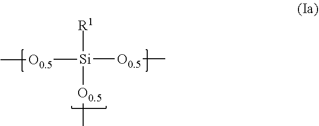

wherein R¹ is hydrogen, a mono- to trivalent, linear, branched or cyclic, saturated or unsaturated, C₁₋₃₀ aliphatic hydrocarbon group, or a mono- to trivalent, C₆₋₃₀ aromatic hydrocarbon group,
the aliphatic hydrocarbon group and the aromatic hydrocarbon group are each unsubstituted or substituted with fluorine, hydroxy or C₁₋₈ alkoxy,
in the aliphatic hydrocarbon group and the aromatic hydrocarbon group, methylene is not replaced, or one or more methylene are replaced with oxy, imide or carbonyl, provided that R¹ is neither hydroxy nor alkoxy, and
when R¹ is divalent or trivalent, R¹ connects each Si contained in a plurality of repeating units;
(II) an ionic liquid;
(III) an acid; and
(IV) a solvent.

Further, the method for manufacturing a cured film according to the present invention comprises applying the above-mentioned composition above a substrate to form a coating film, and heating the coating film.

Further, the method for manufacturing an electronic device according to the present invention comprises the above-mentioned method for manufacturing a cured film.

### Effects of the Invention

The polysiloxane composition according to the present invention can be cured at a lower temperature than the temperature range adopted for a general thermally curable composition. The polysiloxane composition according to the present invention is good in storage stability. The obtained cured film has a small amount of film shrinkage, is also good in film thickness uniformity, has a small elastic modulus, and thus can follow the deformation of a substrate. Additionally, it has good filling properties even when applied on a substrate having a high aspect ratio. Since the obtained cured film has good planarization and electrical insulation characteristics, it can be suitably used for an interlayer insulating film of semiconductor devices, a passivation film, a substrate planarization film, an anti-reflective film, an optical filter, a high-intensity light emitting diode, a touch panel, a solar cell and an optical device such as an optical waveguide device.

### DETAILED DESCRIPTION OF THE INVENTION

### Mode for Carrying Out the Invention

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization can be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (IV) or another component.

Hereinafter, embodiments of the present invention are described in detail.

### Polysiloxane Composition

The polysiloxane composition according to the present invention (hereinafter referred to as the composition) comprises (I) a polysiloxane having a certain structure, (II) an ionic liquid, (III) an acid, and (IV) a solvent. Hereinafter, each component contained in the composition according to the present invention is described in detail.

### (I) Polysiloxane

The polysiloxane used in the present invention includes a repeating unit represented by the following formula (Ia) and has silanol at the end or side chain.

Silanol means one in which an OH group is directly bonded to a Si skeleton. It is one in which hydroxy is directly bonded to a silicon atom in a polysiloxane containing the above-mentioned repeating unit of the formula (Ia) or the like. Silanol is formed by replacing —O_{0.5}— with —O_{0.5}H of the above formula. The content of silanol in the polysiloxane varies depending on the synthesis conditions of the polysiloxane, for example, the mixing ratio of the monomers and the type of the reaction catalyst. The content of this silanol can be evaluated by quantitative infrared absorption spectrum measurement. The absorption band assigned to silanol (SiOH) appears as an absorption band having a peak in the range of 900±100 cm⁻¹ of the infrared absorption spectrum. The higher the content of silanol, the higher the strength of this absorption band.

When the polysiloxane used in the present invention is measured and analyzed by an FT-IR method, S2/S1 that is a ratio of an integrated intensity S1 of an absorption band assigned to Si-O in the range of 1100±100 cm⁻¹ to an integrated intensity S2 of an absorption band assigned to SiOH in the range of 900±100 cm⁻¹ is 0.010 to 0.10, preferably 0.015 to 0.090, and more preferably 0.020 to 0.080.

The integrated intensity of the absorption band is determined in consideration of noise in the infrared absorption spectrum. In a typical infrared absorption spectrum of polysiloxane, an absorption band assigned to Si—OH having a peak in the range of 900±100 cm⁻¹ and an absorption band assigned to a Si—O having a peak in the range of 1100±100 cm⁻¹ are confirmed. The integrated intensity of these absorption bands can be measured as an area taking account of a baseline for which noise and the like are considered. There is a possibility that the foot of the absorption band assigned to Si—OH and the foot of the absorption band assigned to Si—O are overlapped; however, in such a case, the wavenumber corresponding to the minimal point between the two absorption bands in the spectrum is set as their boundary. The same applies to the case where the foot of the other absorption band overlaps with the foot of the absorption band assigned to Si—OH or Si—O.

The formula (Ia) is as follows:

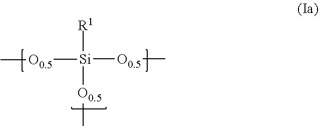

wherein
R¹ is hydrogen, a mono- to trivalent, linear, branched or cyclic, saturated or unsaturated, C₁₋₃₀ aliphatic hydrocarbon group, or a mono- to trivalent, C₆₋₃₀ aromatic hydrocarbon group, preferably hydrogen, linear, branched or cyclic, C₁₋₆ alkyl, or C₆₋₁₀ aryl, more preferably hydrogen, methyl, ethyl or phenyl, further preferably methyl or phenyl.

The aliphatic hydrocarbon group and the aromatic hydrocarbon group are each unsubstituted or substituted with fluorine, hydroxy or C₁₋₈ alkoxy,
in the aliphatic hydrocarbon group and the aromatic hydrocarbon group, methylene is not replaced, or one or more methylene are replaced with oxy, imide or carbonyl, provided that R¹ is neither hydroxy nor alkoxy, and
when R¹ is divalent or trivalent, R¹ connects each Si contained in a plurality of repeating units.

In the formula (Ia), when R¹ is a monovalent group, examples of R¹ include, in addition to hydrogen, (i) alkyl such as methyl, ethyl, propyl, butyl, pentyl, hexyl, heptyl, octyl and decyl, (ii) aryl such as phenyl, tolyl and benzyl, (iii) fluoroalkyl such as trifluoromethyl, 2,2,2-trifluoroethyl and 3,3,3-trifluoropropyl, (iv) fluoroaryl, (v) cycloalkyl such as cyclohexyl, (vi) nitrogen-containing groups having an amino or imide structure such as isocyanates and aminos, and (vii) oxygen-containing groups having an epoxy structure such as glycidyl, or an acryloyl or methacryloyl structure. Preferred are methyl, ethyl, propyl, butyl, pentyl, hexyl, phenyl, tolyl, glycidyl and isocyanate. As the fluoroalkyl, perfluoroalkyl, particularly trifluoromethyl and pentafluoroethyl are preferable. It is preferable that R¹ is methyl because the raw material is easily available, the film hardness after curing is high, and the film has high chemical resistance. Further, it is also preferable that R¹ is phenyl because the solubility of polysiloxane in the solvent is increased and the cured film becomes less likely to crack.

When R¹ is a divalent or trivalent group, R¹ is, for example, preferably (i) a group obtained by removing two or three hydrogen from alkane such as methane, ethane, propane, butane, pentane, hexane, heptane, octane and decane, (ii) a group obtained by removing two or three hydrogen from cycloalkane such as cycloheptane, cyclohexane and cyclooctane, (iii) a group obtained by removing two or three hydrogen from an aromatic compound composed only of a hydrocarbon such as benzene and naphthalene, (iv) a group obtained by removing two or three hydrogen from a nitrogen- and/or oxygen-containing cyclic aliphatic hydrocarbon compound containing an amino group, an imino group and/or a carbonyl group, such as piperidine, pyrrolidine and isocyanurate. It is more preferably (iv), in order to improve pattern sagging and increase adhesion to the substrate.

The number of the repeating units represented by the formula (Ia) is preferably 80% or more, more preferably 90% or more, based on the total number of the repeating units contained in the polysiloxane molecule. In an embodiment of the present invention, the polysiloxane preferably substantially includes a repeating unit represented by the formula (Ia), and more preferably includes a repeating unit represented by the formula (Ia).

The polysiloxane used in the present invention can further comprise a repeating unit represented by the following formula (Ib):

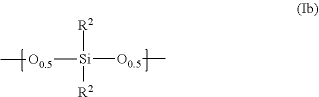

wherein R² is each independently hydrogen, a mono- to trivalent, linear, branched or cyclic, saturated or unsaturated, C₁₋₃₀ aliphatic hydrocarbon group, or a mono- to trivalent, C₆₋₃₀ aromatic hydrocarbon group, preferably hydrogen, linear, branched or cyclic, C₁₋₆ alkyl, or C₆₋₁₀ aryl, more preferably hydrogen, methyl, ethyl or phenyl, further preferably methyl.

The aliphatic hydrocarbon group and the aromatic hydrocarbon group are each unsubstituted or substituted with fluorine, hydroxy or C₁₋₈ alkoxy,
in the aliphatic hydrocarbon group and the aromatic hydrocarbon group, methylene is not replaced, or one or more methylene are replaced with oxy, imide or carbonyl, provided that R² is neither hydroxy nor alkoxy, and
when R² is divalent or trivalent, R² connects each Si contained in a plurality of repeating units.

By having the repeating unit of the formula (Ib), the polysiloxane can be partially formed into a straight-chain structure. However, it is preferable that the straight-chain structural portions are less because the heat resistance is lowered. In particular, the number of the repeating unit of the formula (Ib) is 20% or less, more preferably 10% or less, based on the total number of the repeating units of polysiloxane.

The polysiloxane used in the present invention can further comprise a repeating unit represented by the following formula (Ic), but the repeating unit represented by the formula (Ic) is preferably small from the viewpoint of compatibility with a solvent, suppression of crack generation, and a low elastic modulus, and particularly, the repeating unit represented by the formula (Ic) is preferably 10% or less, more preferably 5% or less, based on the total number of repeating units contained in the polysiloxane molecule. In a preferred embodiment, the polysiloxane used in the present invention is substantially free of the repeating unit represented by the formula (Ic), and more preferably free of the repeating unit represented by the formula (Ic), that is, 0%.

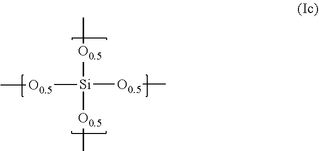

The polysiloxane used in the present invention also can comprise a repeating unit other than the repeating units represented by the formulas (Ia), (Ib), and (Ic), but the number thereof is preferably 20% or less, more preferably 10% or less, based on the total number of the repeating units contained in the polysiloxane molecule. It is also a preferred embodiment of the present invention that it contains no repeating unit other than the above.

The mass average molecular weight of the polysiloxane used in the present invention is preferably 500 to 10,000, more preferably 500 to 4,000 in terms of solubility in an organic solvent, coatability above a substrate, and solubility in an alkaline developer, and further preferably 1,000 to 3,000. The mass average molecular weight is the mass average molecular weight in terms of polystyrene, which can be measured by the gel permeation chromatography based on polystyrene.

The polysiloxane can be used alone or in combination of two or more of any of these. The content of the polysiloxane is preferably 0.5 to 70 mass %, more preferably 1 to 60 mass %, based on the total mass of the polysiloxane composition.

Such a polysiloxane can be obtained by hydrolysis and condensation of, for example, a silicon compound represented by the formula (ia), if necessary, in the presence of an acidic catalyst or a basic catalyst:

R^{1′}[Si(OR^{a})₃]ₚ (ia)
wherein p is an integer of 1 to 3;
R^{1′} is hydrogen, a mono- to trivalent, linear, branched or cyclic, saturated or unsaturated, C₁₋₃₀ aliphatic hydrocarbon group, or a mono- to trivalent, C₆₋₃₀ aromatic hydrocarbon group;
the aliphatic hydrocarbon group and the aromatic hydrocarbon group are each unsubstituted or substituted with fluorine, hydroxy or C₁₋₈ alkoxy;
in the aliphatic hydrocarbon group and the aromatic hydrocarbon group, methylene is not replaced, or one or more methylene are replaced with oxy, imide or carbonyl, provided that R^{1′} is neither hydroxy nor alkoxy; and
R^{a} is C₁₋₁₀ alkyl, preferably methyl, ethyl, n-propyl, isopropyl and n-butyl.

Exemplified embodiments of the silicon compound represented by the general formula (ia) include methyltrimethoxysilane, methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, phenyltrimethoxysilane, phenyltriethoxysilane, trifluoromethyltrimethoxysilane, trifluoromethyltriethoxysilane, 3,3,3-trifluoropropyltrimethoxysilane, tris-(3-trimethoxysilylpropyl)isocyanurate, tris-(3-triethoxysilylpropyl)isocyanurate and tris-(3-trimethoxysilylethyl)isocyanurate, and among them, methyltrimethoxysilane, methyltriethoxysilane, methyltripropoxysilane and phenyltrimethoxysilane are preferred.

The silicon compounds can be used in combination of two or more of any of these.

### (II) Ionic Liquid

The composition according to the present invention comprises an ionic liquid.

The ionic liquid is a salt that exists as a liquid in a wide temperature range, and is a liquid consisting only of ions. Generally, a salt having a melting point of 100° C. or lower is defined as an ionic liquid. The ionic liquid used in the present invention has a melting point of 100° C. or lower, preferably 80° C. or lower, more preferably 60° C. or lower, further preferably 30° C. or lower.

The ionic liquid used in the present invention is preferably a basic ionic liquid, preferably one composed of a combination of a strong base and a weak acid.

The cation of the ionic liquid is preferably at least one cation selected from the group consisting of an imidazolium type ion, a pyrrolidinium type ion, a piperidinium type ion, a pyridinium type ion, and an ammonium type ion, and more preferably an imidazolium type ion.

The imidazolium type ion is preferably represented by the following formula (A):

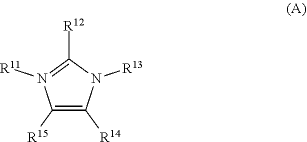

wherein
R¹¹, R¹², R¹³, R¹⁴ and R¹⁵ are each independently hydrogen, linear or branched, C₁₋₁₈ alkyl, cyclic C₅₋₁₂ alkyl, or C₆₋₁₄ aryl.

Exemplified embodiments of the imidazolium type ion include 1-methylimidazolium, 1-methyl-2-ethylimidazolium, 1-methyl-3-octylimidazolium, 1,2-dimethylimidazolium, 1,3-dimethylimidazolium, 2,3-dimethylimidazolium, 3,4-dimethylimidazolium, 1,2,3-trimethylimidazolium, 1,3,4-trimethylimidazolium, 1,3,4,5-tetramethylimidazolium, 1-ethylimidazolium, 1-ethyl-2-methyl imidazolium, 1-ethyl-3-methylimidazolium, 1-ethyl-2,3-dimethylimidazolium, 2-ethyl-3,4-dimethylimidazolium, 1-propyl imidazolium, 1-propyl-2-methyl imidazolium, 1-propyl-3-methylimidazolium, 1-propyl-2,3-dimethylimidazolium, 1,3-dipropylimidazolium, 1-butylimidazolium, 1-butyl-2-methylimidazolium, 1-butyl-3-methylimidazolium, 1-butyl-4-methylimidazolium, 1-butyl-2,3-dimethylimidazolium, 1-butyl-3,4-dimethylimidazolium, 1-butyl-3,4,5-trimethylimidazolium, 1-butyl-2-ethylimidazolium, 1-butyl-3-ethylimidazolium, 1-butyl-2-ethyl-5-methylimidazolium, 1,3-dibutylimidazolium, 1,3-dibutyl-2-methylimidazolium, 1-pentylimidazolium, 1-pentyl-2-methylimidazolium, 1-pentyl-3-methyl imidazolium, 1-pentyl-2,3-dimethylimidazolium, 1-hexylimidazolium, 1-hexyl-2-methylimidazolium, 1-hexyl-3-methylimidazolium, 1-hexyl-2,3-dimethylimidazolium, 1-octyl-2-methylimidazolium, 1-octyl-3-methylimidazolium, 1-decyl-3-methylimidazolium, 1-dodecyl-3-methylimidazolium, 1-tetradecyl-3-methylimidazolium, 1-hexadecyl-3-methylimidazolium and 1-benzyl-3-methylimidazolium, and preferably 1-ethyl-3-methylimidazolium, 1-ethyl-2,3-dimethylimidazolium, 1,3-dimethylimidazolium, 1,2,3-trimethylimidazolium, 1-propyl-3-methylimidazolium, 1-propyl-2,3-dimethylimidazolium, 1-butyl-3-methylimidazolium, 1-butyl-2,3-dimethylimidazolium and 1-octyl-3-methylimidazolium.

The pyrrolidinium type ion is preferably represented by the following formula (B):

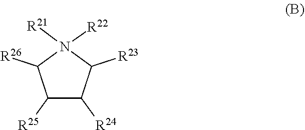

wherein
R²¹, R²², R²³, R²⁴, R²⁵ and R²⁶ are each independently hydrogen, linear or branched C₁₋₁₈ alkyl, cyclic C₅₋₁₂ alkyl, or C₆₋₁₄ aryl.

Exemplified embodiments of the pyrrolidinium type ion include 1-methyl-1-ethylpyrrolidinium, 1-methyl-1-propylpyrrolidinium, 1-methyl-1-butylpyrrolidinium, 1-methyl-1-pentylpyrrolidinium, 1-methyl-1-hexylpyrrolidinium and 1-methyl-1-octylpyrrolidinium, and preferably 1-methyl-1-propylpyrrolidinium.

The piperidinium type ion is preferably represented by the following formula (C):

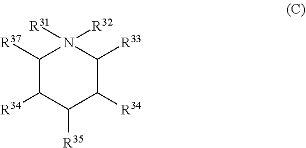

wherein
R³¹, R³², R³³, R³⁴, R³⁵, R³⁶ and R³⁷ are each independently hydrogen, linear or branched C₁₋₁₈ alkyl, cyclic C₅₋₁₂ alkyl, or C₆₋₁₄ aryl.

Exemplified embodiments of the piperidinium type ion include 1-methyl-1-ethylpiperidinium, 1-methyl-1-propylpiperidinium, 1-methyl-1-butylpiperidinium, 1-methyl-1-pentylpiperidinium, 1-methyl-1-hexylpiperidinium and 1-methyl-1-octylpiperidinium, and preferably 1-methyl-1-butylpiperidinium.

The pyridinium type ion is preferably represented by the following formula (D):

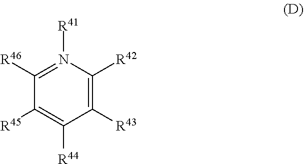

wherein
R⁴¹, R⁴², R⁴³, R⁴⁴, R⁴⁵ and R⁴⁶ are each independently hydrogen, linear or branched C₁₋₁₈ alkyl, cyclic C₅₋₁₂ alkyl, or C₆₋₁₄ aryl.

Exemplified embodiments of the pyridinium type ion include 1-methylpyridinium, 1-ethylpyridinium, 1-propylpyridinium, 1-butylpyridinium, 1-pentylpyridinium, 1-hexylpyridinium, 1-octylpyridinium, 1-methyl-3-ethylpyridinium, 1-methyl-4-ethylpyridinium, 1-methyl-3-butylpyridinium, 1-methyl-4-butylpyridinium, 1-ethyl-3-methylpyridinium, 1-ethyl-4-methylpyridinium, 1-propyl-3-methylpyridinium, 1-propyl-4-methylpyridinium, 1-butyl-3-methylpyridinium, 1-butyl-4-methylpyridinium, 1-hexyl-4-methylpyridinium and 1-octyl-4-methylpyridinium, and preferably 1-butylpyridinium and 1-ethyl-4-methylpyridinium.

The ammonium type ion is preferably represented by the following formula (E):

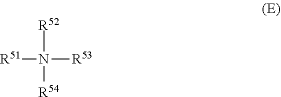

wherein
R⁵¹, R⁵², R⁵³ and R⁵⁴ are each independently linear or branched, C₁₋₁₈ alkyl, linear or branched, C₁₋₁₈ hydroxyalkyl, cyclic C₅₋₁₂ alkyl, or C₆₋₁₄ aryl.

Exemplified embodiments of the ammonium type ion include trimethylethylammonium, trimethylbutylammonium, triethylmethylammonium, tripropylmethylammonium, tributylmethylammonium, trihexylmethylammonium, trioctylmethylammonium, tetrabutylammonium, 2-hydroxyethyltrimethylammonium and tris(2-hydroxyethyl)methylammonium, and preferably tetrabutylammonium, tributylmethylammonium and 2-hydroxyethyltrimethylammonium.

The anion of the ionic liquid is preferably at least one anion selected from the group consisting of a formate ion, an acetate ion, a propionate ion, a lactate ion, an oleate ion, a salicylate ion, a dicyanamide ion, a cyanamide ion, a thiocyanate ion, a methyl sulfate ion, an ethyl sulfate ion, a hydrogen sulfate ion, a methane sulfonate ion, a trifluoromethane sulfonate ion, a p-toluene sulfonate ion, a bis(trifluoromethylsulfonyl)imide ion, a bis(fluorosulfonyl)imide ion, a methyl carbonate ion, a hydrogen carbonate ion, a diethyl phosphate ion, a dibutyl phosphate ion, a hexafluorophosphate ion, a tetrafluoroborate ion, a chlorine ion and a bromine ion, and more preferably an acetate ion, a dicyanamide ion, a cyanamide ion, a chlorine ion and a bromine ion.

In a preferred embodiment, exemplified embodiments of the ionic liquid include trimethylbutylammonium bis(trifluoromethylsulfonyl)imide, tributylmethylammonium dicyanamide, tributylmethylammonium bis(trifluoromethylsulfonyl)imide, tris(2-hydroxyethyl)methylammonium methylsulfate, 2-hydroxyethyltrimethylammonium acetate, 2-hydroxyethyltrimethylammonium lactate, 2-hydroxyethyltrimethylammonium salicylate, tetrabutylammonium chloride, 1,3-dimethylimidazolium methylsulfate, 1,2,3-trimethylimidazolium methylsulfate, 1-ethyl-3-methylimidazolium acetate, 1-ethyl-3-methylimidazolium dicyanamide, 1-ethyl-3-methylimidazolium methylsulfate, 1-ethyl-3-methylimidazolium thiocyanate, 1-ethyl-2,3-dimethylimidazolium bis(trifluoromethylsulfonyl)imide, 1-propyl-3-methylimidazolium acetate, 1-propyl-3-methylimidazolium bis(trifluoromethylsulfonyl)imide, 1-propyl-2,3-dimethylimidazolium bis(trifluoromethylsulfonyl)imide, 1-butyl-3-methylimidazolium acetate, 1-butyl-3-methylimidazolium dicyanamide, 1-butyl-3-methylimidazolium thiocyanate, 1-butyl-3-methylimidazolium bromide, 1-butyl-3-methylimidazolium hexafluorophosphate, 1-butyl-3-methylimidazolium tetrafluoroborate, 1-butyl-2,3-dimethylimidazolium bis(trifluoromethylsulfonyl)imide, 1-octyl-3-methylimidazolium acetate, 1-octyl-3-methylimidazolium bromide, 1-octyl-3-methylimidazolium tetrafluoroborate, 1-methyl-1-butylpyrrolidinium dicyanamide, 1-methyl-1-octylpyrrolidinium bis(trifluoromethylsulfonyl)imide, 1-methyl-1-butylpiperidinium bis(trifluoromethylsulfonyl)imide, 1-ethyl-3-methylpyridinium ethylsulfate, 1-butyl-4-methylpyridinium bis(trifluoromethylsulfonyl)imide and 1-butylpyridinium tetrafluoroborate.

In a more preferred embodiment, the ionic liquid has an imidazolium type ion as a cation and an acetate as an anion, and exemplified embodiments thereof include 1-ethyl-3-methylimidazolium acetate, 1-propyl-3-methylimidazolium acetate, 1-butyl-3-methylimidazolium acetate and 1-octyl-3-methylimidazolium acetate.

The ionic liquid has catalytic action that promotes the curing of polysiloxane, and it is assumed that the curing can be completed even at a relatively low temperature.

The mixing ratio of the ionic liquid to the polysiloxane (ionic liquid/polysiloxane) is preferably 0.000010 to 0.10, more preferably 0.000020 to 0.10 in terms of mass ratio. This is because, due to being in such a range, the effect of low temperature curing is more exhibited and the density of the cured film tends to be increased.

Since the ionic liquid can be uniformly present in the composition as compared with the commonly used curing accelerator (for example, a thermal base generator), it is assumed that the ionic liquid exhibits effects on suppressing voids. When the composition comprises an ionic liquid, an effect of improving adhesion to the substrate can also be expected.

The ionic liquid can be used alone or in combination of two or more of any of these. The content of the ionic liquid is preferably 0.00010 to 4.0 mass %, more preferably 0.00020 to 3.2 mass %, based on the total mass of the composition according to the present invention.

### (III) Acid

The composition according to the present invention comprises an acid.

The acid can be an inorganic acid or an organic acid, but is preferably an organic acid, more preferably a carboxylic acid, further preferably a monocarboxylic acid or a dicarboxylic acid, further more preferably a dicarboxylic acid.

Examples of the monocarboxylic acid include acetic acid, formic acid, propionic acid, butyric acid, valeric acid and acrylic acid, and acetic acid is preferable.

Examples of the dicarboxylic acid include oxalic acid, maleic acid, fumaric acid, phthalic acid, succinic acid, glutaconic acid, aspartic acid, glutamic acid, malic acid, citraconic acid, acetylenedicarboxylic acid, itaconic acid, mesaconic acid, 3-aminohexandioic acid and malonic acid, preferably oxalic acid, maleic acid, fumaric acid, phthalic acid, succinic acid, malic acid, citraconic acid, acetylenedicarboxylic acid or malonic acid, more preferably oxalic acid, maleic acid, fumaric acid, phthalic acid, citraconic acid or acetylenedicarboxylic acid.

It is preferable that the acid has high sublimability, which is to sublimate when heated for curing. In particular, the sublimation temperature is preferably 90 to 300° C., more preferably 90 to 250° C. This is because the residual amount of the cured film is reduced by the sublimation of the acid when the coating film is cured.

Although not wishing to be bound by theory, as described above, the ionic liquid functions as a catalyst that accelerates the curing of polysiloxane at a low temperature. With respect to the composition comprising an ionic liquid, a polysiloxane and a solvent, there is a case that curing is proceeded even during long-term storage at room temperature, resulting in gelation or the like. On the other hand, it is assumed that by combining an acid, it is possible to suppress the catalytic action of the ionic liquid and exhibit good storage stability. It is assumed that the sublimation of the acid during heating for curing makes the catalytic action of the ionic liquid be exhibited and cure at a low temperature. In order to exhibit better storage stability and low temperature curability, the present invention preferably comprises a combination of an ionic liquid and a carboxylic acid, more preferably a combination of an ionic liquid and oxalic acid, maleic acid, fumaric acid, phthalic acid, citraconic acid or acetylenedicarboxylic acid, further preferably a combination of an ionic liquid in which the cation is an imidazolium type ion and the anion is an acetate ion, and maleic acid.

In a preferred embodiment, exemplified embodiments of the combination of the ionic liquid and the acid (ionic liquid/acid) include tributylmethylammonium dicyanamide/acetic acid, tris(2-hydroxyethyl)methylammonium methylsulfate/acetic acid, 2-hydroxyethyltrimethylammonium acetate/acetic acid, 2-hydroxyethyltrimethylammonium lactate/acetic acid, 2-hydroxyethyltrimethylammonium salicylate/acetic acid, tetrabutylammonium chloride/acetic acid, 1-ethyl-3-methylimidazolium acetate/acetic acid, 1-ethyl-3-methylimidazolium dicyanamide/acetic acid, 1-ethyl-3-methylimidazolium methylsulfate/acetic acid, 1-ethyl-3-methylimidazolium thiocyanate/acetic acid, 1-propyl-3-methylimidazolium acetate/acetic acid, 1-butyl-3-methylimidazolium acetate/acetic acid, 1-butyl-3-methylimidazolium dicyanamide/acetic acid, 1-butyl-3-methylimidazolium thiocyanate/acetic acid, 1-butyl-3-methylimidazolium bromide/acetic acid, 1-octyl-3-methylimidazolium acetate/acetic acid, 1-octyl-3-methylimidazolium bromide/acetic acid, tributylmethylammonium dicyanamide/succinic acid, tris(2-hydroxyethyl)methylammonium methylsulfate/succinic acid, 2-hydroxyethyltrimethylammonium acetate/succinic acid, 2-hydroxyethyltrimethylammonium lactate/succinic acid, 2-hydroxyethyltrimethylammonium salicylate/succinic acid, tetrabutylammonium chloride/succinic acid, 1-ethyl-3-methylimidazolium acetate/succinic acid, 1-ethyl-3-methylimidazolium dicyanamide/succinic acid, 1-ethyl-3-methylimidazolium methylsulfate/succinic acid, 1-ethyl-3-methylimidazolium thiocyanate/succinic acid, 1-propyl-3-methylimidazolium acetate/succinic acid, 1-butyl-3-methylimidazolium acetate/succinic acid, 1-butyl-3-methylimidazolium dicyanamide/succinic acid, 1-butyl-3-methylimidazolium thiocyanate/succinic acid, 1-butyl-3-methylimidazolium bromide/succinic acid, 1-octyl-3-methylimidazolium acetate/succinic acid, 1-octyl-3-methylimidazolium bromide/succinic acid, 1-methyl-1-butylpyrrolidinium dicyanamide/succinic acid, tributylmethylammonium dicyanamide/glutaconic acid, tris(2-hydroxy)ethyl)methylammonium methylsulfate/glutaconic acid, 2-hydroxyethyltrimethylammonium acetate/glutaconic acid, 2-hydroxyethyltrimethylammonium lactate/glutaconic acid, 2-hydroxyethyltrimethylammonium salicylate/glutaconic acid, tetrabutylammonium chloride/glutaconic acid, 1-ethyl-3-methylimidazolium acetate/glutaconic acid, 1-ethyl-3-methylimidazolium dicyanamide/glutaconic acid, 1-ethyl-3-methylimidazolium methylsulfate/glutaconic acid, 1-ethyl-3-methylimidazolium thiocyanate/glutaconic acid, 1-propyl-3-methylimidazolium acetate/glutaconic acid, 1-butyl-3-methylimidazolium acetate/glutaconic acid, 1-butyl-3-methylimidazolium dicyanamide/glutaconic acid, 1-butyl-3-methylimidazolium thiocyanate/glutaconic acid, 1-butyl-3-methylimidazolium bromide/glutaconic acid, 1-octyl-3-methylimidazolium acetate/glutaconic acid, 1-octyl-3-methylimidazolium bromide/glutaconic acid, trimethylbutylammonium bis(trifluoromethylsulfonyl)imide/citraconic acid, tributylmethylammonium dicyanamide/citraconic acid, tributylmethylammonium bis(trifluoromethylsulfonyl)imide/citraconic acid, tris(2-hydroxyethyl)methylammonium methylsulfate/citraconic acid, 2-hydroxyethyltrimethylammonium acetate/citraconic acid, 2-hydroxyethyltrimethylammonium lactate/citraconic acid, 2-hydroxyethyltrimethylammonium salicylate/citraconic acid, tetrabutylammonium chloride/citraconic acid, 1,3-dimethylimidazolium methylsulfate/citraconic acid, 1,2,3-trimethylimidazolium methylsulfate/citraconic acid, 1-ethyl-3-methylimidazolium acetate/citraconic acid, 1-ethyl-3-methylimidazolium dicyanamide/citraconic acid, 1-ethyl-3-methylimidazolium methylsulfate/citraconic acid, 1-ethyl-3-methylimidazolium thiocyanate/citraconic acid, 1-propyl-3-methylimidazolium acetate/citraconic acid, 1-propyl-3-methylimidazolium bis(trifluoromethylsulfonyl)imide/citraconic acid, 1-butyl-3-methylimidazolium acetate/citraconic acid, 1-butyl-3-methylimidazolium dicyanamide/citraconic acid, 1-butyl-3-methylimidazolium thiocyanate/citraconic acid, 1-butyl-3-methylimidazolium bromide/citraconic acid, 1-butyl-3-methylimidazolium hexafluorophosphate/citraconic acid, 1-butyl-3-methylimidazolium tetrafluoroborate/citraconic acid, 1-octyl-3-methylimidazolium acetate/citraconic acid, 1-octyl-3-methylimidazolium bromide/citraconic acid, 1-octyl-3-methylimidazolium tetrafluoroborate/citraconic acid, 1-methyl-1-butylpyrrolidinium dicyanamide/citraconic acid, 1-methyl-1-octylpyrrolidinium bis(trifluoromethylsulfonyl)imide/citraconic acid, 1-methyl-1-butylpiperidinium bis(trifluoromethylsulfonyl)imide/citraconic acid, 1-ethyl-3-methylpyridinium ethylsulfate/citraconic acid, 1-butyl-4-methylpyridinium bis(trifluoromethylsulfonyl)imide/citraconic acid, 1-butylpyridinium tetrafluoroborate/citraconic acid, trimethylbutylammonium bis(trifluoromethylsulfonyl)imide/acetylenedicarboxylic acid, tributylmethylammonium dicyanamide/acetylenedicarboxylic acid, tributylmethylammonium bis(trifluoromethylsulfonyl)imide/acetylenedicarboxylic acid, tris(2-hydroxyethyl)methylammonium methylsulfate/acetylenedicarboxylic acid, 2-hydroxyethyltrimethylammonium acetate/acetylenedicarboxylic acid, 2-hydroxyethyltrimethylammonium lactate/acetylenedicarboxylic acid, 2-hydroxyethyltrimethylammonium salicylate/acetylenedicarboxylic acid, tetrabutylammonium chloride/acetylenedicarboxylic acid, 1,3-dimethylimidazolium methylsulfate/acetylenedicarboxylic acid, 1,2,3-trimethylimidazolium methylsulfate/acetylenedicarboxylic acid, 1-ethyl-3-methylimidazolium acetate/acetylenedicarboxylic acid, 1-ethyl-3-methylimidazolium dicyanamide/acetylenedicarboxylic acid, 1-ethyl-3-methylimidazolium methylsulfate/acetylenedicarboxylic acid, 1-ethyl-3-methylimidazolium thiocyanate/acetylenedicarboxylic acid, 1-propyl-3-methylimidazolium acetate/acetylenedicarboxylic acid, 1-propyl-3-methylimidazolium bis(trifluoromethylsulfonyl)imide/acetylenedicarboxylic acid, 1-butyl-3-methylimidazolium acetate/acetylenedicarboxylic acid, 1-butyl-3-methylimidazolium dicyanamide/acetylenedicarboxylic acid, 1-butyl-3-methylimidazolium thiocyanate/acetylenedicarboxylic acid, 1-butyl-3-methylimidazolium bromide/acetylenedicarboxylic acid, 1-butyl-3-methylimidazolium hexafluorophosphate/acetylenedicarboxylic acid, 1-butyl-3-methylimidazolium tetrafluoroborate/acetylenedicarboxylic acid, 1-octyl-3-methylimidazolium acetate/acetylenedicarboxylic acid, 1-octyl-3-methylimidazolium bromide/acetylenedicarboxylic acid, 1-octyl-3-methylimidazolium tetrafluoroborate/acetylenedicarboxylic acid, 1-methyl-1-butylpyrrolidinium dicyanamide/acetylenedicarboxylic acid, 1-methyl-1-octylpyrrolidinium bis(trifluoromethylsulfonyl)imide/acetylenedicarboxylic acid, 1-methyl-1-butylpiperidinium bis(trifluoromethylsulfonyl)imide/acetylenedicarboxylic acid, 1-ethyl-3-methylpyridinium ethylsulfate/acetylenedicarboxylic acid, 1-butyl-4-methylpyridinium bis(trifluoromethylsulfonyl)imide/acetylenedicarboxylic acid, 1-butylpyridinium tetrafluoroborate/acetylenedicarboxylic acid, trimethylbutylammonium bis(trifluoromethylsulfonyl)imide/oxalic acid, tributylmethylammonium dicyanamide/oxalic acid, tributylmethylammonium bis(trifluoromethylsulfonyl)imide/oxalic acid, tris(2-hydroxyethyl)methylammonium methylsulfate/oxalic acid, 2-hydroxyethyltrimethylammonium acetate/oxalic acid, 2-hydroxyethyltrimethylammonium lactate/oxalic acid, 2-hydroxyethyltrimethylammonium salicylate/oxalic acid, tetrabutylammonium chloride/oxalic acid, 1,3-dimethylimidazolium methylsulfate/oxalic acid, 1,2,3-trimethylimidazolium methylsulfate/oxalic acid, 1-ethyl-3-methylimidazolium acetate/oxalic acid, 1-ethyl-3-methylimidazolium dicyanamide/oxalic acid, 1-ethyl-3-methylimidazolium methylsulfate/oxalic acid, 1-ethyl-3-methylimidazolium thiocyanate/oxalic acid, 1-propyl-3-methylimidazolium acetate/oxalic acid, 1-propyl-3-methylimidazolium bis(trifluoromethylsulfonyl)imide/oxalic acid, 1-butyl-3-methylimidazolium acetate/oxalic acid, 1-butyl-3-methylimidazolium dicyanamide/oxalic acid, 1-butyl-3-methylimidazolium thiocyanate/oxalic acid, 1-butyl-3-methylimidazolium bromide/oxalic acid, 1-butyl-3-methylimidazolium hexafluorophosphate/oxalic acid, 1-butyl-3-methylimidazolium tetrafluoroborate/oxalic acid, 1-octyl-3-methylimidazolium acetate/oxalic acid, 1-octyl-3-methylimidazolium bromide/oxalic acid, 1-octyl-3-methylimidazolium tetrafluoroborate/oxalic acid, 1-methyl-1-butylpyrrolidinium dicyanamide/oxalic acid, 1-methyl-1-octylpyrrolidinium bis(trifluoromethylsulfonyl)imide/oxalic acid, 1-methyl-1-butylpiperidinium bis(trifluoromethylsulfonyl)imide/oxalic acid, 1-ethyl-3-methylpyridinium ethylsulfate/oxalic acid, 1-butyl-4-methylpyridinium bis(trifluoromethylsulfonyl)imide/oxalic acid, 1-butylpyridinium tetrafluoroborate/oxalic acid, trimethylbutylammonium bis(trifluoromethylsulfonyl)imide/maleic acid, tributylmethylammonium dicyanamide/maleic acid, tributylmethylammonium bis(trifluoromethylsulfonyl)imide/maleic acid, tris(2-hydroxyethyl)methylammonium methylsulfate/maleic acid, 2-hydroxyethyltrimethylammonium acetate/maleic acid, 2-hydroxyethyltrimethylammonium lactate/maleic acid, 2-hydroxyethyltrimethylammonium salicylate/maleic acid, tetrabutylammonium chloride/maleic acid, 1,3-dimethylimidazolium methylsulfate/maleic acid, 1,2,3-trimethylimidazolium methylsulfate/maleic acid, 1-ethyl-3-methylimidazolium acetate/maleic acid, 1-ethyl-3-methylimidazolium dicyanamide/maleic acid, 1-ethyl-3-methylimidazolium methylsulfate/maleic acid, 1-ethyl-3-methylimidazolium thiocyanate/maleic acid, 1-propyl-3-methylimidazolium acetate/maleic acid, 1-propyl-3-methylimidazolium bis(trifluoromethylsulfonyl)imide/maleic acid, 1-butyl-3-methylimidazolium acetate/maleic acid, 1-butyl-3-methylimidazolium dicyanamide/maleic acid, 1-butyl-3-methylimidazolium thiocyanate/maleic acid, 1-butyl-3-methylimidazolium bromide/maleic acid, 1-butyl-3-methylimidazolium hexafluorophosphate/maleic acid, 1-butyl-3-methylimidazolium tetrafluoroborate/maleic acid, 1-octyl-3-methylimidazolium acetate/maleic acid, 1-octyl-3-methylimidazolium bromide/maleic acid, 1-octyl-3-methylimidazolium tetrafluoroborate/maleic acid, 1-methyl-1-butylpyrrolidinium dicyanamide/maleic acid, 1-methyl-1-octylpyrrolidinium bis(trifluoromethylsulfonyl)imide/maleic acid, 1-methyl-1-butylpiperidinium bis(trifluoromethylsulfonyl)imide/maleic acid, 1-ethyl-3-methylpyridinium ethylsulfate/maleic acid, 1-butyl-4-methylpyridinium bis(trifluoromethylsulfonyl)imide/maleic acid, 1-butylpyridinium tetrafluoroborate/maleic acid, trimethylbutylammonium bis(trifluoromethylsulfonyl)imide/fumaric acid, tributylmethylammonium dicyanamide/fumaric acid, tributylmethylammonium bis(trifluoromethylsulfonyl)imide/fumaric acid, tris(2-hydroxyethyl)methylammonium methylsulfate/fumaric acid, 2-hydroxyethyltrimethylammonium acetate/fumaric acid, 2-hydroxyethyltrimethylammonium lactate/fumaric acid, 2-hydroxyethyltrimethylammonium salicylate/fumaric acid, tetrabutylammonium chloride/fumaric acid, 1,3-dimethylimidazolium methylsulfate/fumaric acid, 1,2,3-trimethylimidazolium methylsulfate/fumarate, 1-ethyl-3-methylimidazolium acetate/fumaric acid, 1-ethyl-3-methylimidazolium dicyanamide/fumaric acid, 1-ethyl-3-methylimidazolium methylsulfate/fumaric acid, 1-ethyl-3-methylimidazolium thiocyanate/fumaric acid, 1-propyl-3-methylimidazolium acetate/fumaric acid, 1-propyl-3-methylimidazolium bis(trifluoromethylsulfonyl)imide/fumaric acid, 1-butyl-3-methylimidazolium acetate/fumaric acid, 1-butyl-3-methylimidazolium dicyanamide/fumaric acid, 1-butyl-3-methylimidazolium thiocyanate/fumaric acid, 1-butyl-3-methylimidazolium bromide/fumaric acid, 1-butyl-3-methylimidazolium hexafluorophosphate/fumaric acid, 1-butyl-3-methylimidazolium tetrafluoroborate/fumaric acid, 1-octyl-3-methylimidazolium acetate/fumaric acid, 1-octyl-3-methylimidazolium bromide/fumaric acid, 1-octyl-3-methylimidazolium tetrafluoroborate/fumaric acid, 1-methyl-1-butylpyrrolidinium dicyanamide/fumaric acid, 1-methyl-1-octylpyrrolidinium bis(trifluoromethylsulfonyl)imide/fumaric acid, 1-methyl-1-butylpiperidinium bis(trifluoromethylsulfonyl)imide/fumaric acid, 1-ethyl-3-methylpyridinium ethylsulfate/fumaric acid, 1-butyl-4-methylpyridinium bis(trifluoromethylsulfonyl)imide/fumaric acid, 1-butylpyridinium tetrafluoroborate/fumaric acid, trimethylbutylammonium bis(trifluoromethylsulfonyl)imide/phthalic acid, tributylmethylammonium dicyanamide/phthalic acid, tributylmethylammonium bis(trifluoromethylsulfonyl)imide/phthalic acid, tris(2-hydroxyethyl)methylammonium methylsulfate/phthalic acid, 2-hydroxyethyltrimethylammonium acetate/phthalic acid, 2-hydroxyethyltrimethylammonium lactate/phthalic acid, 2-hydroxyethyltrimethylammonium salicylate/phthalic acid, tetrabutylammonium chloride/phthalic acid, 1,3-dimethylimidazolium methylsulfate/phthalic acid, 1,2,3-trimethylimidazolium methylsulfate/phthalic acid, 1-ethyl-3-methylimidazolium acetate/phthalic acid, 1-ethyl-3-methylimidazolium dicyanamide/phthalic acid, 1-ethyl-3-methylimidazolium methylsulfate/phthalic acid, 1-ethyl-3-methylimidazolium thiocyanate/phthalic acid, 1-propyl-3-methylimidazolium acetate/phthalic acid, 1-propyl-3-methylimidazolium bis(trifluoromethylsulfonyl)imide/phthalic acid, 1-butyl-3-methylimidazolium acetate/phthalic acid, 1-butyl-3-methylimidazolium dicyanamide/phthalic acid, 1-butyl-3-methylimidazolium thiocyanate/phthalic acid, 1-butyl-3-methylimidazolium bromide/phthalic acid, 1-butyl-3-methylimidazolium hexafluorophosphate/phthalic acid, 1-butyl-3-methylimidazolium tetrafluoroborate/phthalic acid, 1-octyl-3-methylimidazolium acetate/phthalic acid, 1-octyl-3-methylimidazolium bromide/phthalic acid, 1-octyl-3-methyl imidazolium tetrafluoroborate/phthalic acid, 1-methyl-1-butylpyrrolidinium dicyanamide/phthalic acid, 1-methyl-1-octylpyrrolidinium bis(trifluoromethylsulfonyl)imide/phthalic acid, 1-methyl-1-butylpiperidinium bis(trifluoromethylsulfonyl)imide/phthalic acid, 1-ethyl-3-methylpyridinium ethylsulfate/phthalic acid, 1-butyl-4-methylpyridinium bis(trifluoromethylsulfonyl)imide/phthalic acid, and 1-butylpyridinium tetrafluoroborate/phthalic acid.

In a more preferred embodiment, exemplified embodiments of the combination of the ionic liquid and the acid (ionic liquid/acid) include trimethylbutylammonium bis(trifluoromethylsulfonyl)imide/citraconic acid, tributylmethylammonium dicyanamide/citraconic acid, tributylmethylammonium bis(trifluoromethylsulfonyl)imide/citraconic acid, tris(2-hydroxyethyl)methylammonium methylsulfate/citraconic acid, 2-hydroxyethyltrimethylammonium acetate/citraconic acid, 2-hydroxyethyltrimethylammonium lactate/citraconic acid, 2-hydroxyethyltrimethylammonium salicylate/citraconic acid, tetrabutylammonium chloride/citraconic acid, 1,3-dimethylimidazolium methylsulfate/citraconic acid, 1,2,3-trimethylimidazolium methylsulfate/citraconic acid, 1-ethyl-3-methylimidazolium acetate/citraconic acid, 1-ethyl-3-methylimidazolium dicyanamide/citraconic acid, 1-ethyl-3-methylimidazolium methylsulfate/citraconic acid, 1-ethyl-3-methylimidazolium thiocyanate/citraconic acid, 1-propyl-3-methylimidazolium acetate/citraconic acid, 1-propyl-3-methylimidazolium bis(trifluoromethylsulfonyl)imide/citraconic acid, 1-butyl-3-methylimidazolium acetate/citraconic acid, 1-butyl-3-methylimidazolium dicyanamide/citraconic acid, 1-butyl-3-methylimidazolium thiocyanate/citraconic acid, 1-butyl-3-methylimidazolium bromide/citraconic acid, 1-butyl-3-methylimidazolium hexafluorophosphate/citraconic acid, 1-butyl-3-methylimidazolium tetrafluoroborate/citraconic acid, 1-octyl-3-methylimidazolium acetate/citraconic acid, 1-octyl-3-methylimidazolium bromide/citraconic acid, 1-octyl-3-methylimidazolium tetrafluoroborate/citraconic acid, 1-methyl-1-butylpyrrolidinium dicyanamide/citraconic acid, 1-methyl-1-octylpyrrolidinium bis(trifluoromethylsulfonyl)imide/citraconic acid, 1-methyl-1-butylpiperidinium bis(trifluoromethylsulfonyl)imide/citraconic acid, 1-ethyl-3-methylpyridinium ethylsulfate/citraconic acid, 1-butyl-4-methylpyridinium bis(trifluoromethylsulfonyl)imide/citraconic acid, 1-butylpyridinium tetrafluoroborate/citraconic acid, trimethylbutylammonium bis(trifluoromethylsulfonyl)imide/acetylenedicarboxylic acid, tributylmethylammonium dicyanamide/acetylenedicarboxylic acid, tributylmethylammonium bis(trifluoromethylsulfonyl)imide/acetylenedicarboxylic acid, tris(2-hydroxyethyl)methylammonium methylsulfate/acetylenedicarboxylic acid, 2-hydroxyethyltrimethylammonium acetate/acetylenedicarboxylic acid, 2-hydroxyethyltrimethylammonium lactate/acetylenedicarboxylic acid, 2-hydroxyethyltrimethylammonium salicylate/acetylene dicarboxylic acid, tetrabutylammonium chloride/acetylenedicarboxylic acid, 1,3-dimethylimidazolium methylsulfate/acetylenedicarboxylic acid, 1,2,3-trimethylimidazolium methylsulfate/acetylenedicarboxylic acid, 1-ethyl-3-methylimidazolium acetate/acetylenedicarboxylic acid, 1-ethyl-3-methylimidazolium dicyanamide/acetylenedicarboxylic acid, 1-ethyl-3-methylimidazolium methylsulfate/acetylenedicarboxylic acid, 1-ethyl-3-methylimidazolium thiocyanate/acetylene dicarboxylic acid, 1-propyl-3-methylimidazolium acetate/acetylenedicarboxylic acid, 1-propyl-3-methylimidazolium bis(trifluoromethylsulfonyl)imide/acetylenedicarboxylic acid, 1-butyl-3-methylimidazolium acetate/acetylenedicarboxylic acid, 1-butyl-3-methylimidazolium dicyanamide/acetylenedicarboxylic acid, 1-butyl-3-methylimidazolium thiocyanate/acetylenedicarboxylic acid, 1-butyl-3-methylimidazolium bromide/acetylenedicarboxylic acid, 1-butyl-3-methylimidazolium hexafluorophosphate/acetylenedicarboxylic acid, 1-butyl-3-methylimidazolium tetrafluoroborate/acetylenedicarboxylic acid, 1-octyl-3-methylimidazolium acetate/acetylenedicarboxylic acid, 1-octyl-3-methylimidazolium bromide/acetylenedicarboxylic acid, 1-octyl-3-methylimidazolium tetrafluoroborate/acetylenedicarboxylic acid, 1-methyl-1-butylpyrrolidinium dicyanamide/acetylenedicarboxylic acid, 1-methyl-1-octylpyrrolidinium bis(trifluoromethylsulfonyl)imide/acetylenedicarboxylic acid, 1-methyl-1-butylpiperidinium bis(trifluoromethylsulfonyl)imide/acetylenedicarboxylic acid, 1-ethyl-3-methylpyridinium ethylsulfate/acetylenedicarboxylic acid, 1-butyl-4-methylpyridinium bis(trifluoromethylsulfonyl)imide/acetylenedicarboxylic acid, 1-butylpyridinium tetrafluoroborate/acetylenedicarboxylic acid, trimethylbutylammonium bis(trifluoromethylsulfonyl)imide/oxalic acid, tributylmethylammonium dicyanamide/oxalic acid, tributylmethylammonium bis(trifluoromethylsulfonyl)imide/oxalic acid, tris(2-hydroxyethyl)methylammonium methylsulfate/oxalic acid, 2-hydroxyethyltrimethylammonium acetate/oxalic acid, 2-hydroxyethyltrimethylammonium lactate/oxalic acid, 2-hydroxyethyltrimethylammonium salicylate/carboxylic acid, tetrabutylammonium chloride/oxalic acid, 1,3-dimethylimidazolium methylsulfate/oxalic acid, 1,2,3-trimethylimidazolium methylsulfate/oxalic acid, 1-ethyl-3-methylimidazolium acetate/oxalic acid, 1-ethyl-3-methylimidazolium dicyanamide/oxalic acid, 1-ethyl-3-methylimidazolium methyl sulfate/oxalic acid, 1-ethyl-3-methylimidazolium thiocyanate/oxalic acid, 1-propyl-3-methylimidazolium acetate/oxalic acid, 1-propyl-3-methylimidazolium bis(trifluoromethylsulfonyl)imide/oxalic acid, 1-butyl-3-methylimidazolium acetate/oxalic acid, 1-butyl-3-methylimidazolium dicyanamide/oxalic acid, 1-butyl-3-methylimidazolium thiocyanate/oxalic acid, 1-butyl-3-methylimidazolium bromide/oxalic acid, 1-butyl-3-methylimidazolium hexafluorophosphate/oxalic acid, 1-butyl-3-methylimidazolium tetrafluoroborate/oxalic acid, 1-octyl-3-methylimidazolium acetate/oxalic acid, 1-octyl-3-methylimidazolium bromide/oxalic acid, 1-octyl-3-methylimidazolium tetrafluoroborate/oxalic acid, 1-methyl-1-butylpyrrolidinium dicyanamide/oxalic acid, 1-methyl-1-octylpyrrolidinium bis(trifluoromethylsulfonyl)imide/oxalic acid, 1-methyl-1-butylpiperidinium bis(trifluoromethylsulfonyl)imide/oxalic acid, 1-ethyl-3-methylpyridinium ethylsulfate/oxalic acid, 1-butyl-4-methylpyridinium bis(trifluoromethylsulfonyl)imide/oxalic acid, 1-butylpyridinium tetrafluoroborate/oxalic acid, trimethylbutylammonium bis(trifluoromethylsulfonyl)imide/maleic acid, tributylmethylammonium dicyanamide/maleic acid, tributylmethylammonium bis(trifluoromethylsulfonyl)imide/maleic acid, tris(2-hydroxyethyl)methylammonium methylsulfate/maleic acid, 2-hydroxyethyltrimethylammonium acetate/maleic acid, 2-hydroxyethyltrimethylammonium lactate/maleic acid, 2-hydroxyethyltrimethylammonium salicylate/maleic acid, tetrabutylammonium chloride/maleic acid, 1,3-dimethylimidazolium methylsulfate/maleic acid, 1,2,3-trimethylimidazolium methylsulfate/maleic acid, 1-ethyl-3-methylimidazolium acetate/maleic acid, 1-ethyl-3-methylimidazolium dicyanamide/maleic acid, 1-ethyl-3-methylimidazolium methylsulfate/maleic acid, 1-ethyl-3-methylimidazolium thiocyanate/maleic acid, 1-propyl-3-methylimidazolium acetate/maleic acid, 1-propyl-3-methylimidazolium bis(trifluoromethylsulfonyl)imide/maleic acid, 1-butyl-3-methylimidazolium acetate/maleic acid, 1-butyl-3-methylimidazolium dicyanamide/maleic acid, 1-butyl-3-methylimidazolium thiocyanate/maleic acid, 1-butyl-3-methylimidazolium bromide/maleic acid, 1-butyl-3-methylimidazolium hexafluorophosphate/maleic acid, 1-butyl-3-methylimidazolium tetrafluoroborate/maleic acid, 1-octyl-3-methylimidazolium acetate/maleic acid, 1-octyl-3-methylimidazolium bromide/maleic acid, 1-octyl-3-methylimidazolium tetrafluoroborate/maleic acid, 1-methyl-1-butylpyrrolidinium dicyanamide/maleic acid, 1-methyl-1-octylpyrrolidinium bis(trifluoromethylsulfonyl)imide/maleic acid, 1-methyl-1-butylpiperidinium bis(trifluoromethylsulfonyl)imide/maleic acid, 1-ethyl-3-methylpyridinium ethylsulfate/maleic acid, 1-butyl-4-methylpyridinium bis(trifluoromethylsulfonyl)imide/maleic acid, 1-butylpyridinium tetrafluoroborate/maleic acid, trimethylbutylammonium bis(trifluoromethylsulfonyl)imide/fumaric acid, tributylmethylammonium dicyanamide/fumaric acid, tributylmethylammonium bis(trifluoromethylsulfonyl)imide/fumaric acid, tris(2-hydroxyethyl)methylammonium methylsulfate/fumaric acid, 2-hydroxyethyltrimethylammonium acetate/fumaric acid, 2-hydroxyethyltrimethylammonium lactate/fumaric acid, 2-hydroxyethyltrimethylammonium salicylate/fumaric acid, tetrabutylammonium chloride/fumaric acid, 1,3-dimethylimidazolium methylsulfate/fumaric acid, 1,2,3-trimethylimidazolium methylsulfate/fumaric acid, 1-ethyl-3-methylimidazolium acetate/fumaric acid, 1-ethyl-3-methylimidazolium dicyanamide/fumaric acid, 1-ethyl-3-methylimidazolium methylsulfate/fumaric acid, 1-ethyl-3-methylimidazolium thiocyanate/fumaric acid, 1-propyl-3-methylimidazolium acetate/fumaric acid, 1-propyl-3-methylimidazolium bis(trifluoromethylsulfonyl)imide/fumaric acid, 1-butyl-3-methylimidazolium acetate/fumaric acid, 1-butyl-3-methylimidazolium dicyanamide/fumaric acid, 1-butyl-3-methylimidazolium thiocyanate/fumaric acid, 1-butyl-3-methylimidazolium bromide/fumaric acid, 1-butyl-3-methylimidazolium hexafluorophosphate/fumaric acid, 1-butyl-3-methylimidazolium tetrafluoroborate/fumaric acid, 1-octyl-3-methylimidazolium acetate/fumaric acid, 1-octyl-3-methylimidazolium bromide/fumaric acid, 1-octyl-3-methylimidazolium tetrafluoroborate/fumaric acid, 1-methyl-1-butylpyrrolidinium dicyanamide/fumaric acid, 1-methyl-1-octylpyrrolidinium bis(trifluoromethylsulfonyl)imide/fumaric acid, 1-methyl-1-butylpiperidinium bis(trifluoromethylsulfonyl)imide/fumaric acid, 1-ethyl-3-methylpyridinium ethylsulfate/fumaric acid, 1-butyl-4-methylpyridinium bis(trifluoromethylsulfonyl)imide/fumaric acid, 1-butylpyridinium tetrafluoroborate/fumaric acid, trimethylbutylammonium bis(trifluoromethylsulfonyl)imide/phthalic acid, tributylmethylammonium dicyanamide/phthalic acid, tributylmethylammonium bis(trifluoromethylsulfonyl)imide/phthalic acid, tris(2-hydroxyethyl)methylammonium methylsulfate/phthalic acid, 2-hydroxyethyltrimethylammonium acetate/phthalic acid, 2-hydroxyethyltrimethylammonium lactate/phthalic acid, 2-hydroxyethyltrimethylammonium salicylate/phthalic acid, tetrabutylammonium chloride/phthalic acid, 1,3-dimethylimidazolium methylsulfate/phthalic acid, 1,2,3-trimethylimidazolium methylsulfate/phthalic acid, 1-ethyl-3-methylimidazolium acetate/phthalic acid, 1-ethyl-3-methylimidazolium dicyanamide/phthalic acid, 1-ethyl-3-methylimidazolium methylsulfate/phthalic acid, 1-ethyl-3-methylimidazolium thiocyanate/phthalic acid, 1-propyl-3-methylimidazolium acetate/phthalic acid, 1-propyl-3-methylimidazolium bis(trifluoromethylsulfonyl)imide/phthalic acid, 1-butyl-3-methylimidazolium acetate/phthalic acid, 1-butyl-3-methylimidazolium dicyanamide/phthalic acid, 1-butyl-3-methylimidazolium thiocyanate/phthalic acid, 1-butyl-3-methylimidazolium bromide/phthalic acid, 1-butyl-3-methyl imidazolium hexafluorophosphate/phthalic acid, 1-butyl-3-methylimidazolium tetrafluoroborate/phthalic acid, 1-octyl-3-methylimidazolium acetate/phthalic acid, 1-octyl-3-methylimidazolium bromide/phthalic acid, 1-octyl-3-methylimidazolium tetrafluoroborate/phthalic acid, 1-methyl-1-butylpyrrolidinium dicyanamide/phthalic acid, 1-methyl-1-octylpyrrolidinium bis(trifluoromethylsulfonyl)imide/phthalic acid, 1-methyl-1-butylpiperidinium bis(trifluoromethylsulfonyl)imide/phthalic acid, 1-ethyl-3-methylpyridinium ethylsulfate/phthalic acid, 1-butyl-4-methylpyridinium bis(trifluoromethylsulfonyl)imide/phthalic acid, and 1-butylpyridinium tetrafluoroborate/phthalic acid.

In a further, more preferable embodiment, exemplified embodiments of the combination of the ionic liquid and the acid (ionic liquid/acid) include 1-ethyl-3-methylimidazolium acetate/maleic acid, 1-propyl-3-methylimidazolium acetate/maleic acid, 1-butyl-3-methylimidazolium acetate/maleic acid, and 1-octyl-3-methylimidazolium acetate/maleic acid.

The mixing ratio of the ionic liquid to the acid (ionic liquid/acid) is preferably 0.10 to 1.0, and more preferably 0.20 to 1.0, at an equivalence ratio. This is because when the equivalence ratio is less than 0.10, the density of the cured film tends to decrease, and when it exceeds 1.0, the storage stability tends to decrease.

The acid can be used alone or in combination of two or more of any of these. The content of the acid is preferably 0.00020 to 10.0 mass %, more preferably 0.005 to 10.0 mass %, further preferably 0.001 to 8.0 mass %, based on the total mass of the composition according to the present invention.

### (IV) Solvent

The solvent is not particularly limited as long as it uniformly dissolves or disperses the above-mentioned components (I) to (III) and additives added as needed. Examples of the solvent that can be used in the present invention include ethylene glycol monoalkyl ethers such as ethylene glycol monomethyl ether, ethylene glycol monoethyl ether, ethylene glycol monopropyl ether and ethylene glycol monobutyl ether; diethylene glycol dialkyl ethers such as diethylene glycol dimethyl ether, diethylene glycol diethyl ether, diethylene glycol dipropyl ether and diethylene glycol dibutyl ether; ethylene glycol alkyl ether acetates such as methyl cellosolve acetate, ethyl cellosolve acetate; propylene glycol monoalkyl ethers such as propylene glycol monomethyl ether (PGME) and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons such as benzene, toluene and xylene; ketones such as methyl ethyl ketone, acetone, methyl amyl ketone, methyl isobutyl ketone and cyclohexanone; alcohols such as ethanol, propanol, butanol, hexanol, cyclohexanol, ethylene glycol, glycerin, 3-methoxybutanol and 1,3-butanediol; esters such as ethyl lactate, butyl acetate, 3-methoxybutyl acetate, ethyl 3-ethoxy-propionate and methyl 3-methoxypropionate; and cyclic esters such as γ-butyrolactone, and preferably PGME, 3-methoxybutanol, 1,3-butanediol, PGMEA, ethyl lactate, butyl acetate, 3-methoxybutyl acetate. The solvent can be used alone or in combination of two or more of any of these.

So as to make workability improved by the adopted coating method, and in consideration of the permeability of the solution into the fine trenches and the film thickness required outside the trenches, the content of the solvent in the composition according to the present invention can be appropriately selected depending on the mass average molecular weight of the polysiloxane, distribution and structure thereof. The content of the solvent is preferably 50 to 98 mass %, more preferably 60 to 98 mass %, based on the total mass of the composition according to the present invention.

Although the composition according to the present invention essentially includes the above-mentioned (I) to (IV), further compounds can be optionally combined. The materials that can be combined are as described below. The content of the components other than (I) to (IV) in the entire composition is preferably 10 mass % or less, and more preferably 5 mass % or less, based on the total mass of the composition.

The composition according to the present invention can optionally comprise other additives. Examples of such additives include a surfactant, an adhesion enhancer, an antifoaming agent, a heat curing accelerator and the like.

The surfactant is added for the purpose of improving coating properties, developability, and the like. Examples of the surfactant that can be used in the present invention include nonionic surfactants, anionic surfactants, amphoteric surfactants, and the like.

Examples of the nonionic surfactant include, polyoxyethylene alkyl ethers such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene alcohol derivatives such as polyethoxylate of acetylene alcohol; acetylene glycol; acetylene glycol derivatives such as polyethoxylate of acetylene glycol; fluorine-containing surfactants, such as Fluorad (trade name, 3M Japan Limited), Megaface (trade name, DIC Corporation), Surflon (trade name, AGC Inc.); or organosiloxane surfactants such as KP341 and KF-53 (trade name, Shin-Etsu Chemical Co., Ltd.).

Examples of the above-mentioned acetylene glycol derivatives include 3-methyl-1-butyne-3-ol, 3-methyl-1-pentyne-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexanediol.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid.

Examples of the amphoteric surfactant include 2-alkyl-N-carboxymethyl-N-hydroxyethyl imidazolium betaine and lauric acid amide propyl hydroxysulfone betaine.

These surfactants can be used alone or in combination of two or more of any of these, and the compounding amount thereof is usually 50 to 10,000 ppm, preferably 100 to 8,000 ppm, based on the composition according to the present invention.

The adhesion enhancer has an effect of preventing a pattern from being peeled off due to stress applied after baking when a cured film is formed using the composition according to the present invention. As the adhesion enhancer, imidazoles, silane coupling agents, and the like are preferred. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferable, and 2-hydroxybenzimidazole, benzimidazole, 2-hydroxyimidazole and imidazole are particularly preferably used.

As the antifoaming agent, alcohols (C₁₋₁₈), higher fatty acids such as oleic acid and stearic acid, higher fatty acid esters such as glycerin monolaurate, polyethers such as polyethylene glycols (PEG) (Mn: 200 to 10,000) and polypropylene glycols (PPG) (Mn: 200 to 10,000), silicone compounds such as dimethyl silicone oil, alkyl-modified silicone oil and fluorosilicone oil, and the above-mentioned organosiloxane-based surfactants are included. These can be used alone or in combination of a plurality of these, and the content thereof is preferably 0.1 to 3 mass % based on the total mass of the polysiloxane.

Examples of the heat curing accelerator include a thermal base generator, a thermal acid generator and the like. In the present invention, in the heat curing accelerator, the ionic liquid shall not be contained. Normally, by making a heat curing accelerator contained, the curing rate of the coating film during heating can be increased. However, in the present invention, the ionic liquid fulfills the function of accelerating the curing of polysiloxane, so that curing can be exhibited even if any heat curing accelerator is not contained. Therefore, the content of the heat curing accelerator is preferably 0.01 mass % or less, more preferably 0.001 mass %. It is also a preferred aspect of the present invention that any heat curing accelerator is not contained.

The composition according to the present invention can also be used as a composition having photosensitivity by further making a diazonaphthoquinone derivative, a photoacid generator, a photobase generator, and the like contained. The composition according to the present invention preferably comprises a photoacid generator or a photobase generator and more preferably comprises a photoacid generator. In the present invention, the photoacid generator or the photobase generator refers to a compound that causes bond cleavage under exposure to generate an acid or a base. The generated acid or base is considered to contribute to the polymerization of the polysiloxane. Examples of the light include visible light, ultraviolet rays, infrared rays, X-rays, electron beams, α-rays, and γ-rays. In the present invention, the photoacid generator does not contain a diazonaphthoquinone derivative.

The photoacid generator can be freely selected from those generally used, and examples thereof include a diazomethane compound, a triazine compound, a sulfonic acid ester, a diphenyliodonium salt, a triphenylsulfonium salt, a sulfonium salt, an ammonium salt, a phosphonium salt, and a sulfonimide compound.

Examples of the photoacid generator that can be used, including those described above, include 4-methoxyphenyldiphenylsulfonium hexafluorophosphonate, 4-methoxyphenyldiphenylsulfonium hexafluoroarsenate, 4-methoxyphenyldiphenylsulfonium methanesulfonate, 4-methoxyphenyldiphenylsulfonium trifluoroacetate, triphenylsulfonium tetrafluoroborate, triphenylsulfonium tetrakis(pentafluorophenyl)borate, triphenylsulfonium hexafluorophosphonate, triphenylsulfonium hexafluoroarsenate, 4-methoxyphenyldiphenylsulfonium-p-toluenesulfonate, 4-phenylthiophenyldiphenyltetrafluoroborate, 4-phenylthiophenyldiphenylhexafluorophosphonate, triphenylsulfonium methanesulfonate, triphenylsulfonium trifluoroacetate, triphenylsulfonium-p-toluenesulfonate, 4-methoxyphenyldiphenylsulfonium tetrafluoroborate, 4-phenylthiophenyldiphenylhexafluoroalkenate, 4-phenylthiophenyldiphenyl-p-toluenesulfonate, N-(trifluoromethylsulfonyloxy)succinimide, N-(trifluoromethylsulfonyloxy)phthalimide, 5-norbornene-2,3-dicarboximidyl triflate, 5-norbornene-2,3-dicarboimidyl-p-toluenesulfonate, 4-phenylthiophenyldiphenyltrifluoromethanesulfonate, 4-phenylthiophenyldiphenyldiphenyltrifluoroacetate, N-(trifluoromethylsulfonyloxy)diphenylmaleimide, N-(trifluoromethylsulfonyloxy)bicyclo[2.2.1]hepto-5-ene-2,3-dicarboximide, N-(trifluoromethylsulfonyloxy)naphthylimide, and N-(nonafluorobutylsulfonyloxy)naphthylimide.

Examples of the photobase generator include multi-substituted amide compounds having amide groups, lactams, imide compounds, and compounds having those structures.

An ionic photobase generator containing an amide anion, a methide anion, a borate anion, a phosphate anion, a sulfonate anion, a carboxylate anion, or the like as an anion can also be used.

### Method for Manufacturing a Cured Film

The method for manufacturing a cured film according to the present invention comprises applying the composition according to the present invention above a substrate to form a coating film, and heating the coating film. In the present invention, “above a substrate” shall include a case where the composition is directly applied on the substrate and a case where the composition is applied on the substrate via one or more intermediate layers. The method for forming a cured film is described in process order as follows.

### (1) Coating Process

The shape of the substrate is not particularly limited and can be freely selected depending on the purpose. However, the composition according to the present invention is characterized in that it easily penetrates into narrow trenches and the like and can form a uniform cured film even inside the trenches, and therefore can be applied on a substrate with trenches and holes having a high aspect ratio. In particular, it can be applied on a substrate with at least one trench having a width of the deepest portion of 0.2 μm or less and an aspect ratio of 2 or more, and the like. The shape of the trench is not particularly limited, and the cross section can be any shape such as a rectangular shape, a forward tapered shape, a reverse tapered shape, and a curved surface shape. Both ends of the trench can be open or closed.

As a typical example of a substrate with at least one trench having a high aspect ratio, a substrate for an electronic device comprising a transistor element, a bit line, a capacitor, and the like is referred. In the production of such electronic devices, there is a case that a process of forming an insulating film between a transistor element and a bit line called PMD, between a transistor element and a capacitor, between a bit line and a capacitor or between a capacitor and a metal wiring or an insulating film called IMD between a plurality of metal wirings, or a process of filling isolation trenches is sometimes followed by a through-hole plating process of forming holes penetrating upward and downward through the material for filling a fine trench.

Application can be conducted by any method. It can be freely selected from dip coating, roll coating, bar coating, brush coating, spray coating, doctor coating, flow coating, spin coating, slit coating, and the like. As the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once, twice, or more to make the film thickness of the coating film to be formed as desired one.

### (2) Pre-Baking Process

After forming the coating film by applying the composition, the coating film can be prebaked (preheating treatment) in order to dry the coating film and reduce the residual amount of the solvent in the coating film.

### (3) Curing Process

In the case of a non-photosensitive composition, the coating film is then heated to form a cured film. In the present invention, the cured film means a film having an S2/S1 ratio of less than 0.003.

A hot plate or oven can be used as the heating apparatus used in the curing process. The heating temperature in this curing process is not particularly limited as long as it is the temperature at which the cured film is formed, and it can be freely set. However, if silanol remains, the chemical resistance of the cured film can be insufficient or the dielectric constant of the cured film can be increased. From this point of view, a relatively high heating temperature is generally selected, but when the composition according to the present invention is used, it can be cured at a relatively low temperature. In particular, it is preferable to heat at 500° C. or lower, and more preferably 300° C. or lower. On the other hand, in order to promote the curing reaction, the heating temperature is preferably 120° C. or higher, more preferably 140° C. or higher, and further preferably 170° C. or higher. Further, the heating time is not particularly limited, and when a hot plate is used, it is preferably 1 to 60 minutes, more preferably 1 to 30 minutes. The curing process is preferably performed in an air atmosphere.

Generation of voids can occur in this curing process. In particular, when the number of organic groups contained in the polysiloxane decreases, the generation of voids tends to increase. However, when the composition of the present invention is used, the generation of voids can be suppressed even when the number of organic groups contained in the polysiloxane is small.

In the case of a photosensitive composition, a coating film is formed, and then the surface of the coating film is irradiated with light. As the light source used in light irradiation, any light source conventionally used in a pattern forming method can be used. Examples of such a light source include a lamp such as a high-pressure mercury lamp, a low-pressure mercury lamp, a metal halide, or xenon, a laser diode, and an LED. As the irradiation light, ultraviolet rays such as g-line, h-line, and i-line are usually used. It is common to use light of 360 to 430 nm (high-pressure mercury lamp) for patterning of several μm to several tens of μm, except for ultrafine processing such as semiconductors.

A general photomask can be used to emit light in a pattern. Such a photomask can be freely selected from well-known ones. The environment at the time of irradiation is not particularly limited, but can be generally an ambient atmosphere (air) or a nitrogen atmosphere.

After the exposure, in order to accelerate a reaction between polymers in the film by an acid or base generated at the exposed area, post exposure baking can be performed, if necessary, particularly in the case of a negative type. Unlike a heating step described below, this heating treatment is not performed to completely cure the coating film, but is performed such that only a desired pattern remains on the substrate after the development, and the other portions can be removed by development. In the case of performing post exposure baking, a hot plate, an oven, a furnace, or the like can be used. Since it is not preferable that the acid or base in the exposed area generated by light irradiation is diffused to the unexposed area, the heating temperature should not be excessively high. From such a viewpoint, the range of the heating temperature after the exposure is preferably 40° C. to 150° C., further preferably 60° C. to 120° C.

In order to control the curing rate of the composition, stepwise heating can also be applied if necessary. The atmosphere at the time of heating is not particularly limited, but for the purpose of controlling the curing rate of the composition, the atmosphere can be selected from an inert gas such as nitrogen, a vacuum, a reduced pressure, an oxygen gas, and the like. The heating time is preferably a certain value or more in order to maintain higher uniformity of the temperature history in the wafer plane, and is preferably not excessively long in order to suppress diffusion of the generated acid or base. From such a viewpoint, the heating time is preferably 20 seconds to 500 seconds, further preferably 40 seconds to 300 seconds.

After the exposure, the coating film is subjected to a development treatment. As a developer used during development, any developer conventionally used for development of a photosensitive composition can be used. Examples of a preferable developer include an alkaline developer which is an aqueous solution of an alkaline compound such as tetraalkylammonium hydroxide, choline, an alkali metal hydroxide, an alkali metal metasilicate (hydrate), an alkali metal phosphate (hydrate), ammonia water, an alkylamine, an alkanolamine, or a heterocyclic amine, and a particularly preferable developer is a TMAH aqueous solution. The developing method can also be freely selected from conventionally known methods. Examples thereof include immersing (dipping) in a developer, paddle, shower, slit, cap coating, and spraying. After development is performed with a developer capable of obtaining a pattern by this development, washing is preferably performed.

Thereafter, if necessary, a whole surface exposure (flood exposure) step can also be performed.

The coating film is cured by heating the pattern film obtained after the development. The heating conditions are similar to (3) described above.

The cured film formed using the composition according to the present invention can achieve good transparency, chemical resistance, environmental resistance, electrical insulation, heat resistance and the like. Therefore, it can be suitably used in various fields as an interlayer insulating film for low-temperature polysilicon, a buffer coat film for IC chips, a transparent protective film, and the like.

The method for manufacturing an electronic device comprises the method for manufacturing a cured film according to the above-mentioned present invention.

### EXAMPLES

The present invention is explained more particularly below with reference to Examples and Comparative Examples, but the present invention is not limited by these Examples and Comparative Examples at all.

Gel permeation chromatography (GPC) is measured using Alliance (trademark) e2695 type high-speed GPC system (Japan Waters K.K.) and Super Multipore HZ-N type GPC column (Tosoh Corporation). The measurement is conducted using monodispersed polystyrene as a standard sample and cyclohexene as a developing solvent, under the measuring conditions of a flow rate of 0.6 ml/min and a column temperature of 40° C., and then mass average molecular weight (hereinafter referred to as Mw) is calculated as a relative molecular weight to the standard sample.

### Synthesis Example 1: Polysiloxane A

Into a four-necked flask, 107 g (0.786 mol) of methyltriethoxysilane, 96 g (0.484 mol) of phenyltriethoxysilane, and 300 g of PGMEA are charged and dissolved. Next, 48 g of a 44 mass % aqueous sodium hydroxide solution is added, and the mixture is stirred at 500 rpm at 40° C. for 2 hours. Next, the mixture is neutralized with acetic acid water and stirred for 1 hour. Thereafter, the reaction solution is transferred to the separating funnel and left to stand still for 30 minutes to separate the organic solvent phase and the aqueous phase. The aqueous phase is discarded, and 100 g of pure water is newly added to the organic solvent phase in the separating funnel and shaken, and the alkali component and the water-soluble component remaining in the organic solvent phase are extracted and washed. This washing operation is performed three times. Thereafter, the organic solvent phase washed with pure water is recovered to obtain a polysiloxane A solution. The mass average molecular weight of the polysiloxane A contained in the organic solvent phase is 2,400, and S2/S1 is 0.031. The S2/S1 here is measured using the polysiloxane A solution in the same manner as the method for measuring a S2/S1 of the cured film described later, except that heating is not performed.

### Synthesis Example 2: Polysiloxane B

Into a four-necked flask, 53.7 g (0.394 mol) of methyltrimethoxysilane, 173.7 g (0.876 mol) of phenyltrimethoxysilane, and 300 g of PGMEA are charged and dissolved. Next, 48 g of a 44 mass % aqueous sodium hydroxide solution is added, and the mixture is stirred at 500 rpm at room temperature for 2 hours. Next, the mixture is neutralized with acetic acid water and stirred for 1 hour. Thereafter, the reaction solution is transferred to the separating funnel and left to stand still for 30 minutes to separate the organic solvent phase and the aqueous phase. The aqueous phase is discarded, and 100 g of pure water is newly added to the organic solvent phase in the separating funnel and shaken, and the alkali component and the water-soluble component remaining in the organic solvent phase are extracted and washed. This washing operation is performed three times. Thereafter, the organic solvent phase washed with pure water is recovered to obtain a polysiloxane B solution. The mass average molecular weight of the polysiloxane B contained in the organic solvent phase is 1,600, and S2/S1 is 0.028.

### Synthesis Example 3: Polysiloxane C

Into a four-necked flask, 138.9 g (1.02 mol) of methyltrimethoxysilane, 49.8 g (0.251 mol) of phenyltrimethoxysilane, and 300 g of PGMEA are charged and dissolved. Next, 48 g of a 44 mass % aqueous sodium hydroxide solution is added, and the mixture is stirred at 500 rpm at room temperature for 2 hours. Next, the mixture is neutralized with acetic acid water and stirred for 1 hour. Thereafter, the reaction solution is transferred to the separating funnel and left to stand still for 30 minutes to separate the organic solvent phase and the aqueous phase. The aqueous phase is discarded, and 100 g of pure water is newly added to the organic solvent phase in the separating funnel and shaken, and the alkali component and the water-soluble component remaining in the organic solvent phase are extracted and washed. This washing operation is performed three times. Thereafter, the organic solvent phase washed with pure water is recovered. The mass average molecular weight of the polysiloxane C contained in the organic solvent phase is 1,800, and S2/S1 is 0.032.

### Preparation of Polysiloxane Compositions

With the compositions and contents shown in Table 1 below, polysiloxane compositions of Examples 1 to 5 and Comparative Examples 1 to 3 are prepared. In the tables, the numerical values of the compositions mean mass %.

TABLE 1

| | Example | | | | | Comparative Example | | |
|---|---|---|---|---|---|---|---|---|
| | 1 | 2 | 3 | 4 | 5 | 1 | 2 | 3 |
| (I)Polysiloxane A | 36.0 | 36.0 | 36.0 | — | — | 36.0 | 36.0 | 36.0 |
| (I)Polysiloxane B | — | — | — | 36.0 | — | — | — | — |
| (I)Polysiloxane C | — | — | — | — | 36.0 | — | — | — |
| (II)Ionic liquid A | 0.001 | — | — | — | 0.18 | — | — | — |
| (II)Ionic liquid B | — | 7E−04 | — | — | — | — | — | — |
| (II)Ionic liquid C | — | — | 7E−04 | — | — | — | — | — |
| (II)Ionic liquid D | — | — | — | 2.88 | — | — | — | — |
| Thermal base | — | — | — | — | — | — | — | 0.018 |
| generator A | | | | | | | | |
| (III)Maleic acid | 0.002 | — | — | — | 0.246 | — | 0.007 | — |
| (III)Citraconic acid | — | — | 0.001 | 6.00 | — | — | — | — |
| (III)Oxalic acid | — | 0.001 | — | — | — | — | — | — |
| (IV)PGME | 6.4 | 6.4 | 6.4 | 6.4 | 6.4 | 6.4 | 6.4 | 6.4 |
| (IV)PGMEA | rest | rest | rest | rest | rest | rest | rest | rest |
| Total | 100 | 100 | 100 | 100 | 100 | 100 | 100 | 100 |
| Strage stability | 2% | 2% | 2% | 2% | 2% | 2% | 2% | 7% |
| Film shrinkage | 1.98% | 2.03% | 1.96% | 2.03% | 1.99% | 18.2% | 10.3% | 2.13% |
| S2/S1 after curing | 0.015 | 0.012 | 0.011 | 0.016 | 0.015 | 0.031 | 0.030 | 0.032 |
| Relative diffuse | 0.18 | 0.27 | 0.21 | 0.20 | 0.32 | 0.77 | 0.55 | 2.95 |
| reflectance | | | | | | | | |
| @400 nm (%) | | | | | | | | |

In the table,
Ionic liquid A: 1-ethyl-3-methylimidazolium acetate (EMIMAc),
Ionic liquid B: 1-butyl-3-methylimidazolium dicyanamide,
Ionic liquid C: 2-hydroxyethyltrimethylammonium acetate,
Ionic liquid D: 1-methyl-1-butylpyrrolidinium dicyanamide,
Thermal base generator A: manufactured by San-Apro Ltd.

### Storage Stability

The Mw of the polysiloxane composition is measured immediately after preparation and after storage at 40° C. for 7 days, and the storage stability is evaluated by the following formula. Results are shown in Table 1.

$$Storage stability ( \% ) = ( Mw ( after storage ) - Mw ( before storage ) ) / Mw ( before storage ) \times 100$$

### Film Shrinkage

The polysiloxane composition is applied on a 4-inch Si wafer at 1,000 rpm using a spin coater (1HDX2, manufactured by Mikasa Co., Ltd.). The coated film thickness is measured at 19 points on the diameter using a spectroscopic ellipsometer (M-2000V, manufactured by J. A. Woollam) and the average value thereof is used. The coated wafer is cured in the air at 200° C. for 2 minutes. The cured film thickness is measured in the same manner as the coated film thickness. The film shrinkage is evaluated by the following formula. Results are shown in Table 1.

$$Film shrinkage ( \% ) = ( coated film thickness - cured film thickness ) / coated film thickness \times 100$$

### S2/S1 After Curing

The polysiloxane composition is dropped on a 4-inch Si wafer, spin-coated at 1,000 rpm, and then cured on a hot plate at 150° C. for 2 minutes. Measurement of the FT-IR spectrum is performed at room temperature using FTIR-6100 (JASCO Corporation). In consideration of noise, a baseline correction is conducted, and the integrated intensity of an absorption band (S2) assigned to Si—OH having a peak in the range of 900±100 cm⁻¹ and the integrated intensity of an absorption band (S1) assigned to Si—O having a peak in the range of 1,100±100 cm⁻¹ are measured, thereby calculating a value of S2/S1. Results are shown in Table 1.

Incidentally, there is a possibility that the foot of the absorption band assigned to Si—OH and the foot of the absorption band assigned to Si—O are overlapped; however, in such a case, the wavenumber corresponding to the minimal point between the two absorption bands in the spectrum is set as their boundary. The same applies to the case where the foot of the other absorption band overlaps with the foot of the absorption band assigned to Si—OH or Si—O.

### Relative Diffuse Reflectance

The polysiloxane composition is dropped on a 4-inch Si wafer, spin-coated at 1,000 rpm, and then cured on a hot plate at 200° C. for 2 minutes. An integrating sphere attachment device ISR-2600Plus (SHIMADZU CORPORATION) is attached to a spectrophotometer UV-2600 (SHIMADZU CORPORATION), and the relative diffuse reflectance (%) when light having a wavelength of 400 nm is incident from the polysiloxane cured film side (incident light) 0° is measured with barium sulfate as a standard plate while the standard plate is regarded as 100%. Results are shown in Table 1.

### Cured Film Appearance

When each of the compositions of Example 1 and Comparative Example 1 is applied above a 4-inch Si wafer at 1,000 rpm using a spin coater and heated on a hot plate at 200° C. for 2 minutes to be cured and the appearance of the cured film is visually observed, a uniform cured film is formed in Example 1, but coating unevenness is observed in Comparative Example 1.

### Example 6

To a solution containing 100 parts by mass of the polysiloxane A obtained in Synthesis Example 1, 0.003 parts by mas of the ionic liquid A, 0.006 parts by mass of maleic acid, 1.0 part by mass of “NAI-105” (Midori Kagaku Co., Ltd.) as a photoacid generator, and 0.3 parts by mass of “KF-53” (Shin-Etsu Chemical Co., Ltd.) are added, and PGMEA is added to prepare a solution containing 35 mass % of components other than the solvent, thereby obtaining a composition. The composition is applied above a silicon wafer by spin coating and then prebaked on a hot plate at 100° C. for 90 seconds to adjust the average film thickness to 2 μm. Exposure is performed using a g-, h-line exposure machine, post exposure baking is performed on a hot plate at 100° C. for 90 seconds, development is performed using a 2.38 mass % TMAH aqueous solution, and rinsing with pure water is performed for 30 seconds. It is found that the composition is negative type photosensitive since the contact hole (C/H) pattern of 10 μm is absent. When a substrate having a C/H pattern is cured on a hot plate at 200° C. for 2 minutes and the elastic modulus is measured using an indentation hardness meter “ENT-2100” (ELIONIX INC.), the elastic modulus is 3.82 GPa.

1. A polysiloxane composition comprising:
(I) a polysiloxane including a repeating unit represented by the formula (Ia) and having silanol at the end or side chain, wherein when the polysiloxane is measured and analyzed by an FT-IR method, S2/S1 that is a ratio of an integrated intensity S1 of an absorption band assigned to Si—O in a range of 1100±100 cm⁻¹ to an integrated intensity S2 of an absorption band assigned to SiOH in a range of 900±100 cm⁻¹ is 0.010 to 0.10, 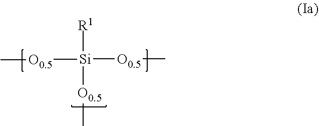
wherein R¹ is hydrogen, a mono- to trivalent, linear, branched or cyclic, saturated or unsaturated, C₁₋₃₀ aliphatic hydrocarbon group, or a mono- to trivalent, C₆₋₃₀ aromatic hydrocarbon group,
the aliphatic hydrocarbon group and the aromatic hydrocarbon group are each unsubstituted or substituted with fluorine, hydroxy or C₁₋₈ alkoxy,
in the aliphatic hydrocarbon group and the aromatic hydrocarbon group, methylene is not replaced, or one or more methylene are replaced with oxy, imide or carbonyl, provided that R¹ is neither hydroxy nor alkoxy, and
when R¹ is divalent or trivalent, R¹ connects each Si contained in a plurality of repeating units;
(II) an ionic liquid;
(III) an acid; and
(IV) a solvent.

2. The composition according to claim 1, wherein R¹ is hydrogen, a linear, branched or cyclic, C₁₋₆ alkyl, or C₆₋₁₀ aryl.

3. The composition according to claim 1, wherein the cation of the ionic liquid (II) is at least one cation selected from the group consisting of an imidazolium type ion, a pyrrolidinium type ion, a piperidinium type ion, a pyridinium type ion, and an ammonium type ion.

4. The composition according to claim 1, wherein the anion of the ionic liquid (II) is at least one anion selected from the group consisting of a formate ion, an acetate ion, a propionate ion, a lactate ion, an oleate ion, a salicylate ion, a dicyanamide ion, a cyanamide ion, a thiocyanate ion, a methyl sulfate ion, an ethyl sulfate ion, a hydrogen sulfate ion, a methane sulfonate ion, a trifluoromethane sulfonate ion, a p-toluene sulfonate ion, a bis(trifluoromethylsulfonyl)imide ion, a bis(fluorosulfonyl)imide ion, a methyl carbonate ion, a hydrogen carbonate ion, a diethyl phosphate ion, a dibutyl phosphate ion, a hexafluorophosphate ion, a tetrafluoroborate ion, a chlorine ion, and a bromine ion.

5. The composition according to claim 1, wherein the mass average molecular weight of the polysiloxane (I) is 500 to 10,000 as measured by gel permeation chromatography.

6. The composition according to claim 1, wherein a mixing ratio of the ionic liquid (II) to the polysiloxane (I) (ionic liquid/polysiloxane) is 0.000010 to 0.10 in terms of mass ratio.

7. The composition according to claim 1, wherein a mixing ratio of the ionic liquid (II) to the acid (III) (ionic liquid/acid) is 0.10 to 1.0 at an equivalence ratio.

8. The composition according to claim 1, wherein the acid (III) is an organic acid.

9. The composition according to claim 1, wherein the solvent (IV) is at least one selected from the group consisting of propylene glycol monomethyl ether, 3-methoxybutanol, 1,3-butanediol, propylene glycol monomethyl ether acetate, ethyl lactate, butyl acetate and 3-methoxybutyl acetate.

10. The composition according to claim 1, wherein a content of the solvent (IV) is 50 to 98 mass % based on the total mass of the composition.

11. The composition according to claim 1, further comprising a photoacid generator or a photobase generator.

12. A method for manufacturing a cured film, comprising applying the composition according to claim 1 above a substrate to form a coating film, and heating the coating film.

13. The method for manufacturing a cured film according to claim 12, wherein the heating is performed at a temperature of 120° C. or higher.

14. A method for manufacturing an electronic device, comprising the method for manufacturing a cured film according to claim 12.
